(19) United States
(12) Patent Application Publication
(10) Pub. No.: US 2012/0305973 A1
(43) Pub. Date: Dec. 6, 2012

(54) LIGHT-EMITTING DEVICE AND SURFACE LIGHT SOURCE DEVICE USING THE SAME

(76) Inventors: Yoshihiko Chosa, Kagoshima (JP); Takashi Kuwaharada, Kagoshima (JP); Kiyoshi Fujihara, Hyogo (JP); Kenichi Koya, Kagoshima (JP)

(21) Appl. No.: 13/522,913

(22) PCT Filed: Jan. 25, 2011
(86) PCT No.: PCT/JP2011/000388

§ 371 Date: Jul. 18, 2012

(30) Foreign Application Priority Data
Feb. 8, 2010 (JP) 2010-025096

(51) Int. Cl. H01L 33/60

(52) U.S. Cl. 257/98; 257/E33.061; 257/E33.072

(57) ABSTRACT

To provide a light emitting device which emits high-luminance, uniform white light with reduced variations in luminance, a light emitting element 101 is mounted on a substrate 105 and covered with a wavelength conversion layer 106 of uniform thickness, and then a light scattering layer 107 made of a translucent resin containing a light reflecting material is formed. As the light scattering layer 107, a high density region 109 in which a density of the light reflecting material is high is formed immediately above a central part of a light emitting surface of the light emitting element 101, and a low density region 110 in which the density of the light reflecting material is low is formed around a region immediately above the central part of the light emitting surface of the light emitting element. A translucent resin layer 108 is formed on the light scattering layer 107.

### TECHNICAL FIELD

The present invention relates to light emitting devices, and surface light sources using the same. In particular, the present invention relates to a light emitting device including a semiconductor light emitting element and a wavelength conversion layer, and a surface light source using the same.

### BACKGROUND ART

Light emitting devices having a downsized, long-life, and low-power semiconductor light emitting element have widely been used in various lighting applications. In addition, light emitting devices have been developed and commercialized which emit white light by combining the semiconductor light emitting device and, for example, a fluorescent material capable of absorbing light of the light emitting element and converting the absorbed light into light of different color. The light emitting device capable of emitting the white light has rapidly been spread as a backlight of a liquid crystal display panel of a flat liquid crystal television. In this application, the light emitting device has been required to be downsized, to show high luminance, and to irradiate a wider range with uniform white light. For example, Patent Document 1 describes a light emitting device capable of emitting uniform white light, i.e., capable of reducing color shading.

According to Patent Document 1, as shown in FIG. 10, a fluorescent material-containing resin 2 corresponding to light beams outgoing from a light emitting device 1 in various directions is provided with a uniform thickness. Thus, in converting the outgoing light beams from the light emitting device 1 with the fluorescent material-containing resin 2, an amount of first light emitted from the light emitting element 1 and an amount of wavelength-converted second light are equalized in each of the directions when viewed from the outside of a light emitting device. Thus, for example, white light obtained by mixing blue light as the first light and yellow light as the second light is made uniform.

Patent Document 2 describes another configuration which can make the color of light uniform.

According to Patent Document 2, as shown in FIG. 11, a fluorescent material resin 12 is formed to cover at least an upper surface of a light emitting element 11, and a translucent resin (a light diffusion layer) 13 is formed on the fluorescent material resin 12.

In this configuration, first light emitted from the light emitting element 11 and wavelength-converted second light pass through the translucent resin (the light diffusion layer) 13 and are scattered, thereby mixing colors of the lights, and reducing color shading.

### CITATION LIST

### Patent Documents

[Patent Document 1] Japanese Patent Publication No. 2006-295228
[Patent Document 2] International Patent Publication No. WO2005/104247

### SUMMARY OF THE INVENTION

### Technical Problem

In general, the light emitting device emits light from a surface parallel to a substrate. When the light emitting element has higher luminance, a light emitting intensity of a center of the light emitting element is higher. Even when the thickness of the fluorescent material layer is made uniform, the color of the light emitted from the center of the light emitting element is more intense than the wavelength-converted light when viewed from the outside of the light emitting device. Thus, according to Patent Document 1, when the light emitting element which emits the blue light is combined with the fluorescent material which converts the blue light to the yellow light, the light emitted from the center of the light emitting element is bluish white. Since the light emitting intensity is high in the center of the light emitting element as described above, not only the color shading, but also variations in luminance may significantly occur.

According to Patent Document 2, the light diffusion layer mixes the light from the light emitting element and the light converted by the fluorescent material at random, thereby reducing the color shading. However, since the light diffusion layer covers the light emitting element, an amount of light emitted from a peripheral part of the light emitting element in which the light intensity is lower than in the center of the light emitting element is reduced by the light scattering. This increases the variations in luminance.

In view of the foregoing, the present invention is directed to a light emitting device using a high luminance light emitting element. The invention is concerned with providing a light emitting device which can reduce variations in luminance, and can emit uniform white light with less color shading, and providing a surface light source using the light emitting device.

### Solution to the Problem

The light emitting device of the present invention includes: a mount substrate; at least one semiconductor light emitting element; a wavelength conversion layer containing at least one material which absorbs first light emitted from the semiconductor light emitting element, and emits second light having a longer wavelength than the first light; and a light scattering layer containing a reflecting material which reflects the first light and the second light, wherein the light scattering layer is provided above a light emitting surface of the semiconductor light emitting element, and part of the light scattering layer immediately above a central part of the light emitting surface of the semiconductor light emitting element has a higher density of the reflecting material than part of the light scattering layer except for the part immediately above the central part of the light emitting surface.

The reflecting material may be made of an insulator or metal.

The wavelength conversion layer may contain a fluorescent material.

The mount substrate may be made of metal or an insulator which reflects the first light and the second light.

A reflective part which reflects the first light and the second light may be provided around the semiconductor light emitting element.

A layer through which the first light and the second light pass may be formed around the semiconductor light emitting element to be in contact with part of the semiconductor light emitting element except for the light emitting surface.

The light emitting device may further include a lens which collects or scatters the first light and the second light.

The semiconductor light emitting element may be made of a nitride semiconductor.

A surface light source of the present invention includes multiple ones of the light emitting device arranged at regular intervals in a column direction and a line direction.

### Advantages of the Invention

According to the present invention, the high density light reflecting material which is provided immediately above the light emitting surface of the light emitting element scatters the light from the light emitting element and the light from the wavelength conversion layer. This can diffuse an amount of light concentrated in a region immediately above the light emitting element and color of the light from the light emitting element. Thus, uniform light with reduced variations in luminance and reduced color shading can be obtained.

### BRIEF DESCRIPTION OF THE DRAWINGS

FIG. 1 is a cross-sectional view schematically showing a light emitting device of a first embodiment of the present invention.

FIG. 2 is a cross-sectional view schematically showing a light emitting device of a second embodiment of the present invention.

FIG. 3 is a cross-sectional view schematically showing a modified example of the light emitting device of the second embodiment of the present invention.

FIG. 4 is a cross-sectional view schematically showing a modified example of the light emitting device of the second embodiment of the present invention.

FIG. 5 is a top view schematically showing a light emitting device of a third embodiment of the present invention.

FIG. 6 is a cross-sectional view taken along the line A-A′.

FIG. 7 is a cross-sectional view schematically showing a light emitting device of a fourth embodiment of the present invention.

FIG. 8 is a cross-sectional view schematically showing a modified example of the light emitting device of the fourth embodiment of the present invention.

FIG. 9 is a cross-sectional view schematically showing a surface light source of a fifth embodiment of the present invention.

FIG. 10 is a cross-sectional view schematically showing a conventional light emitting device.

FIG. 11 is a cross-sectional view schematically showing the conventional light emitting device.

### DESCRIPTION OF EMBODIMENTS

### First Embodiment

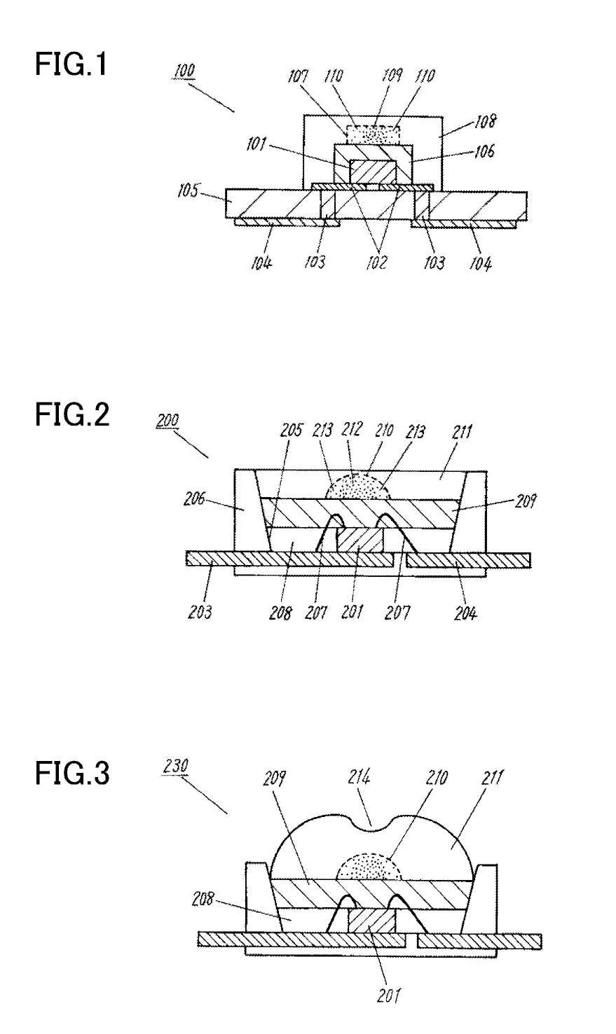

A light emitting device of a first embodiment will be described with reference to FIG. 1.

A light emitting device 100 includes a light emitting element 101 mounted on a ceramic substrate 105. The ceramic substrate 105 includes electrode portions 102 which are formed on an upper surface thereof and correspond to electrodes of the light emitting element 101, and terminals 104 which are formed on a lower surface thereof and electrically connected to the electrode portions 102 via through interconnects 103. The light emitting element 101 has positive and negative electrodes formed on one of surfaces thereof, and is flip-chip mounted on the ceramic substrate 105.

The light emitting element 101 may be made of a nitride semiconductor formed on a sapphire substrate, a SiC substrate, or a GaN substrate, and emits blue light. The ceramic substrate may contain a material which reflects light, such as titanium oxide.

A wavelength conversion layer 106 is formed by providing a first mask (not shown) having an opening larger than the light emitting element 101, and printing a fluorescent material-containing resin by screen printing on the ceramic substrate 105 to cover the light emitting element 101 mounted on the ceramic substrate 105. The fluorescent material may be a YAG fluorescent material or a silicate fluorescent material which absorbs blue light and emits light having a longer wavelength than the blue light, e.g., yellow light, or an oxide, nitride, or oxynitride fluorescent material which emits green or red light. Two or more fluorescent materials, such as a red fluorescent material and a green fluorescent material, may be used in combination. The resin may be an epoxy resin or a silicone resin.

On the wavelength conversion layer 106 immediately above the light emitting element 101, a light scattering layer 107 is formed by printing a translucent resin containing fine titanium oxide particles as a light reflecting material using a second mask (not shown) having an opening immediately above the light emitting element 101. A translucent resin layer 108 which does not contain the light reflecting material is printed on the light scattering layer 107 using a third mask (not shown) having an opening larger than the opening of the second mask.

The translucent resin may be an epoxy resin or a silicone resin used in the fluorescent material-containing resin. Since the resin is formed by printing, a region in which the resin is formed is precisely determined by alignment of the mask. Thus, in the light emitting device 100, a high density region 109 in which a density of the light reflecting material is high can be provided immediately above a central part of a light emitting surface of the light emitting element 101. Even when the light scattering layer 107 is deformed while the printed resin is being cured, the high density region 109 can surely be provided immediately above the central part of the light emitting surface of the light emitting element 101 by optimizing a dimension of the second mask or a curing condition.

The light scattering layer 107 is formed by using two types of translucent resins containing the light reflecting material in different concentrations. Specifically, a translucent resin containing the light reflecting material in a higher concentration is printed to form the high density region 109 immediately above the central part of the light emitting surface of the light emitting element 101. Then, a translucent resin containing the light reflecting material in a lower concentration is printed to form a low density region 110 in which the density of the light reflecting material is low around the high density region 109. The second mask may include at least two types of masks. One is a mask printed immediately above the central part of the light emitting surface of the light emitting element 101, and the other is a mask printed around the high density region 109. A dimension of the low density region 110 in a vertical direction is smaller than a dimension in a lateral direction (a direction rotated by 90° relative to the vertical direction).

In the above-described configuration, the high density region 109 is located immediately above the central part of the light emitting surface of the light emitting element 101 so that light of higher intensity emitted from the central part of the light emitting source is scattered by the high density region 109. The low density region 110 is located above the light emitting element 101 and around the high density region 109. Light emitted from part of the light emitting surface away from the central part has relatively low intensity, and the relatively low intensity light passes through the low density region 110. Thus, variations in luminance of the light emitting device 100 can be reduced. Since the light reflecting material can scatter the light from the light emitting element and the light from the fluorescent material to mix their colors, the light from the light emitting device 100 is uniform white light when viewed from the outside of the light emitting device 100.

When the high density region 109 is located immediately above the central part of the light emitting surface of the light emitting element 101, at least the central part of the light emitting surface (part of the light emitting surface located at the center of the light emitting surface) is covered with the high density region 109 when the light emitting element 101 is viewed from above.

In the present embodiment, titanium oxide has been used as the light reflecting material. However, the same advantages can be obtained as long as a material capable of reflecting or scattering the light, e.g., metal particles, or other insulating materials, is used.

The wavelength conversion layer made of the fluorescent material-containing resin and the translucent resin layer containing the light reflecting material have been formed by screen printing. However, these layers may be formed in an intended region by ink jet printing, potting, or spraying using a mask.

As an example of the wavelength conversion layer, the fluorescent material-containing resin has been described. However, the present invention can provide the similar advantages when a sheet-like fluorescent material layer, such as a ceramic substrate containing a fluorescent material, is provided on the light emitting surface of the light emitting element, or the fluorescent material is adhered to the light emitting surface of the light emitting element.

In the present embodiment, the nitride semiconductor light emitting element which emits the blue light has been combined with the fluorescent material. However, the variations in luminance can be reduced and the light of uniform color can be obtained when a semiconductor light emitting element which emits ultraviolet light is combined with the fluorescent material to obtain white light emission.

### Second Embodiment

Relative to the first embodiment, a configuration in which efficiency of light extraction from the light emitting element is improved will be described with reference to FIG. 2. A light emitting device 200 having a light emitting element 201 includes a first metal frame 203 which is electrically connected to one of electrodes of the light emitting element 201, a second metal frame 204 which is electrically connected to the other electrode of the light emitting element 201, and a resin 206 which fixes the metal frames 203 and 204, and has a reflective surface 205 which surrounds the light emitting element 201 and reflects light. Surfaces of the metal frames 203 and 204 reflect light emitted by the light emitting element 201 and light emitted by a fluorescent material described later.

The resin 206 may contain a material which reflects the light, such as titanium oxide. The light emitting element 201 is provided on the first metal frame 203, and the electrodes of the light emitting element are electrically connected to the first metal frame 203 and the second metal frame 204 through wires 207, respectively.

A translucent resin layer 208 is formed between side surfaces of the light emitting element 201 and the reflective surface 205 by potting so that light from the side surfaces of the light emitting element 201 is efficiently reflected by the reflective surface 205. A wavelength conversion layer 209 made of a fluorescent material-containing resin is formed on the translucent resin layer 208. With the provision of the translucent resin layer 208, a region including the light emitting element 201 and the translucent resin layer 208 functions as a quasi-light emitting part.

A light scattering layer 210 is formed on the wavelength conversion layer 209 immediately above a central part of a light emitting surface (an upper surface) of the light emitting element 201 by applying a translucent resin containing fine titanium oxide particles as a light reflecting material by ink jet printing, and a translucent resin layer 211 containing no light reflecting material is formed to cover the light scattering layer 210. Since the resin is applied by ink jet printing, the mask used in the first embodiment is no longer required, thereby simplifying the fabrication process. Even when the sprayed ink is blurred, a high density region 212 in which a density of the light reflecting material is high can be formed immediately above the central part of the light emitting surface of the light emitting element 201, and a low density region 213 in which the density of the light reflecting material is low can be formed around the region immediately above the central part of the light emitting surface of the light emitting element 201 by optimizing thixotropy of the translucent resin containing the light reflecting material, or the particle size of the light reflecting material.

According to the present embodiment, the reflective surface 205 is provided to efficiently extracting the light emitted from the side surfaces of the light emitting element 201 in an upward direction. Thus, the light emitting device can be provided with high luminance, reduced variations in luminance, and reduced color shading, in addition to the advantages of the first embodiment.

In the present embodiment, the translucent resin layer 211 has been described as a layer merely covering the wavelength conversion layer 209. However, the translucent resin layer 211 may be in the shape of a lens which can collect or disperse the light. Particularly when the light emitting device of the present invention is applied to a surface light source for a liquid crystal panel, the translucent resin layer 211 in the shape of a lens, like that of a light emitting device 230 shown in FIG. 3 in view of light distribution, can achieve wide light distribution.

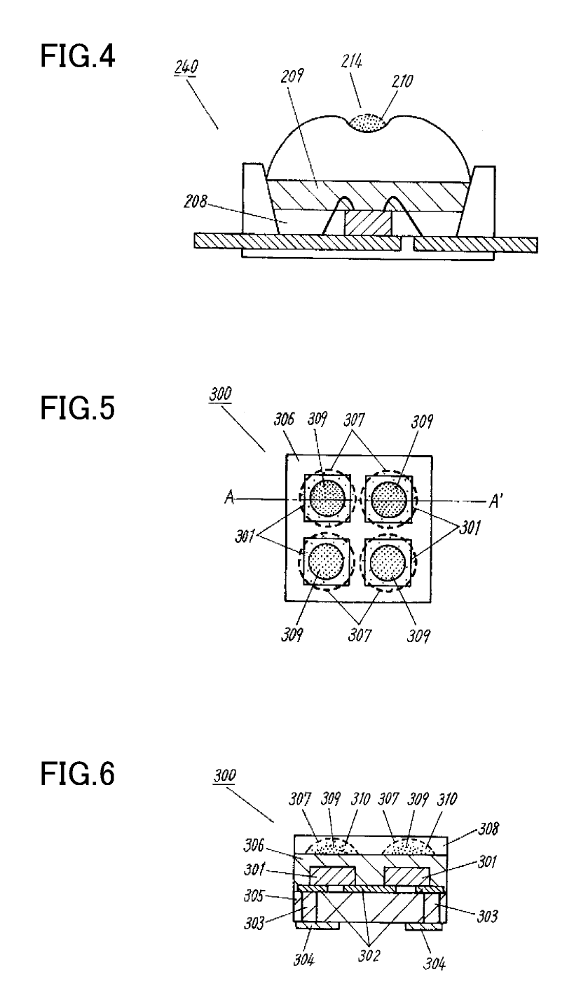

When the lens which is recessed immediately above the light emitting element as shown in FIG. 3 is used, the translucent resin containing the light reflecting material may be applied in a recess 214 to form the light scattering layer 210 like that of a light emitting device 240 shown in FIG. 4.

### Third Embodiment

A light emitting device 300 including a plurality of light emitting elements to pursue the higher luminance will be described with reference to FIGS. 5 and 6. In this embodiment, a plurality of light emitting elements 301, 301, . . . are provided, and intervals between the light emitting elements are reduced to downsize the light emitting device. Accordingly, space above and on the sides of the light emitting element 301 is small. Thus, the color shading is caused by difference in intensity of the light emitting elements 301 rather than difference in thickness of the fluorescent material-containing resin in the light emitting elements 301. The plurality of light emitting elements 301 are flip-chip mounted on a ceramic substrate 305 including electrode portions 302 on an upper surface thereof, through interconnects 303, and terminals 304 on a lower surface thereof.

A wavelength conversion layer 306 is formed by printing a fluorescent material-containing resin by screen printing on the ceramic substrate 305 on which the light emitting element 301 is mounted, and curing the resin. Then, a light scattering layer 307 is formed by applying a translucent resin containing a light reflecting material by ink jet printing, and curing the resin. Then, a translucent resin layer 308 containing no light reflecting material is applied.

According to the present embodiment, the plurality of light emitting elements are used. Even in this case, a high density region 309 in which a density of the light reflecting material is high is provided immediately above the central part of the light emitting surface, and a low density region 310 in which the density of the light reflecting material is low is provided around the region immediately above the central part of the light emitting surface of the light emitting element 301, like the first and second embodiments. This can provide the light emitting device capable of reducing variations in luminance, and emitting uniform white light at high luminance.

### Fourth Embodiment

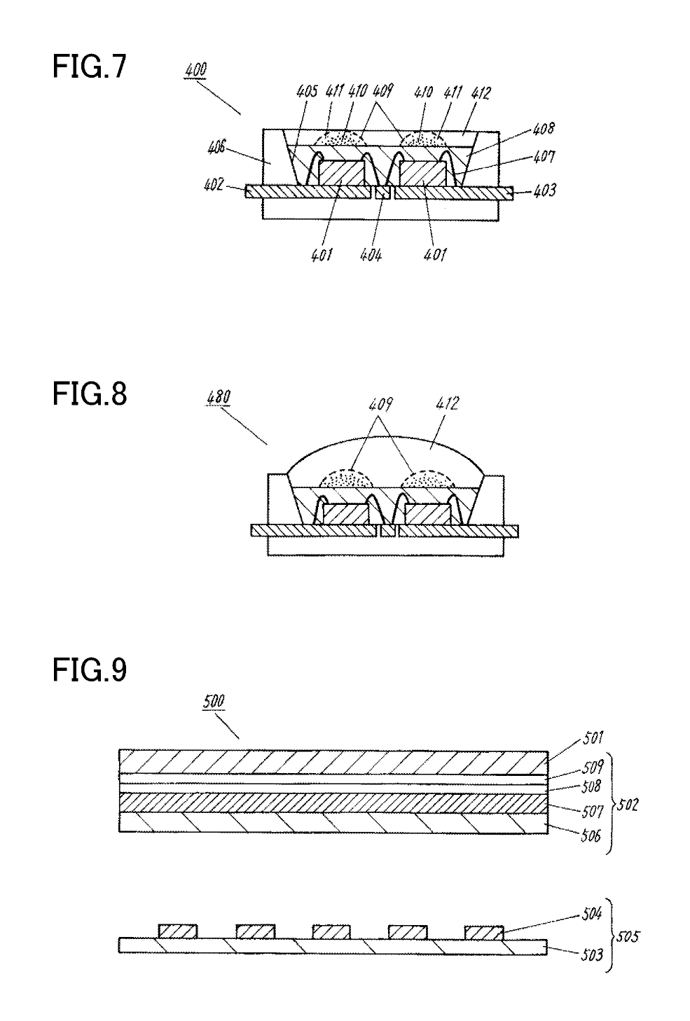

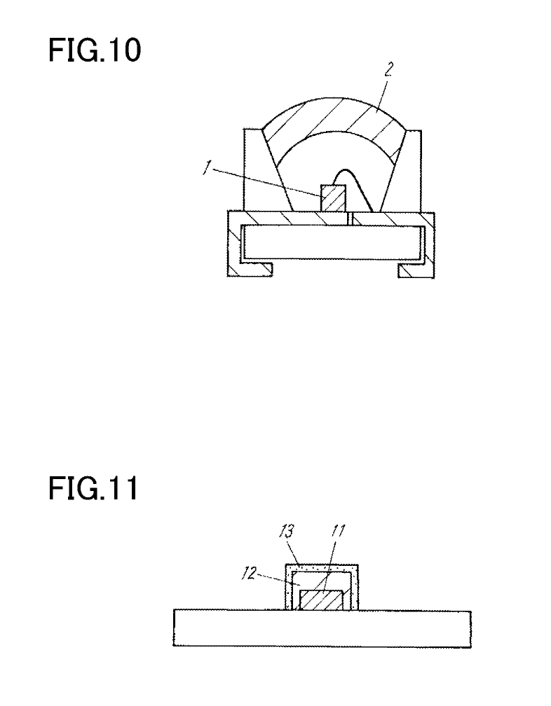

A light emitting device including a plurality of light emitting elements to improve the efficiency of light extraction will be described with reference to FIG. 7. A light emitting device 400 includes a first metal frame 402 and a second metal frame 403 which are electrically connected to one of electrodes of a plurality of light emitting elements 401, 401 mounted on the first metal frame 402 and the second metal frame 403, a third metal frame 404 which is electrically connected to the other electrodes of the light emitting elements 401. A resin 406 is formed to fix the metal frames, and has a reflective surface 405 which surrounds the plurality of light emitting elements 401 and reflects light. The resin 406 may contain a material which reflects the light, such as titanium oxide.

The plurality of light emitting elements 401 and the metal frames 402, 403, and 404 are electrically connected through wires 407. The light emitting elements 401 may electrically connected in series or parallel, depending on the use of the light emitting device 400.

A wavelength conversion layer 408 made of a fluorescent material-containing resin is formed to cover the plurality of light emitting elements 401. A light scattering layer 409 is formed by applying a translucent resin containing fine titanium oxide particles as a light reflecting material by ink jet printing. A high density region 410 in which a density of the light reflecting material is high is provided immediately above a central part of a light emitting surface of each of the light emitting elements 401, and a low density region 411 in which the density of the light reflecting material is low is provided around the region immediately above the central part of the light emitting surface of each of the light emitting elements 401. Then, a translucent resin layer 412 containing no light reflecting material is formed to cover the high and low density regions.

According to the present embodiment, light emitted in a lateral direction from the plurality of light emitting elements 401, 401 is efficiently extracted upward of the light emitting device 400 by the reflective surface 405. Thus, as compared with the third embodiment, the light emitting device can emit uniform white light with higher luminance and reduced variations in luminance.

In the present embodiment, the translucent resin layer 412 has been described as a layer merely covering the wavelength conversion layer 408. However, the translucent resin layer 412 may be in the shape of a lens like a light emitting device 480 which can collect or disperse the light as shown in FIG. 8.

In the third embodiment and the present embodiment, the intervals between the plurality of light emitting elements are small, and the light emitting device is downsized. Thus, the light emitting device may be a point light source. However, when a translucent resin is provided between the light emitting elements or between the light emitting element and the reflective surface as described in the second embodiment, light distribution of the region where the plurality of light emitting elements are mounted, which is as a light source, can be made uniform.

### Fifth Embodiment

A surface light source using the light emitting device of the embodiment described above will be described with reference to FIG. 9. A backlight 500 includes a liquid crystal panel 501, a dimmer 502 adhered to a back surface of the liquid crystal panel, and a surface light source 505 having light emitting devices 504 mounted on a printed board 503 with a predetermined interval provided between the light emitting devices and the dimmer. The dimmer 502 includes a diffuser 506, a diffusion sheet 507, a first dimmer sheet 508, and a second dimmer sheet 509. The diffuser 506 is a resin plate having a rough surface to scatter light from the surface light source 505.

The backlight 500 has been required to be thin. When the light emitting devices of the first or second embodiment of the present invention capable of emitting the uniform white light with reduced variations in luminance are mounted on the surface light source 505 of FIG. 9, the interval between the dimmer 502 and the surface light source 505 can be reduced, and the number of the light emitting devices per panel can be reduced simultaneously.

This can contribute to reduction of parts count and costs of the backlight, and to reduction of power consumption by reducing the number of the light emitting devices. When the light emitting devices of the third or fourth embodiment are mounted as point light sources on the printed board 503, and a lens (not shown) for wide light distribution is provided thereon, the dimmer 502 can be irradiated with high-luminance uniform light in a wider range, and the number of the light emitting devices can further be reduced.

### INDUSTRIAL APPLICABILITY

The present invention is suitable for a light emitting device as a light source which is required to be able to mix color of light emitted from a semiconductor light emitting element and color of light from a fluorescent material for wavelength conversion of the emitted light, to reduce variations in luminance, and to emit uniform light with reduced color shading, and for a surface light source using the light emitting device.

### DESCRIPTION OF REFERENCE CHARACTERS

101, 201, 301, 401 Light emitting element
100, 200, 230, 240, 300, 400, 480, 504 Light emitting device
102, 302 Electrode portion
103, 303 Through interconnect
104, 304 Terminal
105, 305 Ceramic substrate
106, 209, 306, 408 Wavelength conversion layer
107, 210, 307, 409 Light scattering layer
108, 208, 211, 308, 412 Translucent resin layer
109, 212, 309, 410 Low density region
110, 213, 310, 411 High density region
205, 405 Reflective surface
206, 406 Resin
214 Recess
500 Backlight
501 Liquid crystal panel
502 Dimmer
505 Surface light source

1. A light emitting device, comprising:
a mount substrate;
at least one semiconductor light emitting element;
a wavelength conversion layer containing at least one material which absorbs first light emitted from the semiconductor light emitting element, and emits second light having a longer wavelength than the first light; and
a light scattering layer containing a reflecting material which reflects the first light and the second light, wherein
the light scattering layer is provided above a light emitting surface of the semiconductor light emitting element, and
part of the light scattering layer immediately above a central part of the light emitting surface of the semiconductor light emitting element has a higher density of the reflecting material than part of the light scattering layer except for the part immediately above the central part of the light emitting surface.

2. The light emitting device of claim 1, wherein
the reflecting material is made of an insulator or metal.

3. The light emitting device of claim 1, wherein
the wavelength conversion layer contains a fluorescent material.

4. The light emitting device of claim 1, wherein
the mount substrate is made of metal or an insulator which reflects the first light and the second light.

5. The light emitting device of claim 1, wherein
a reflective part which reflects the first light and the second light is provided around the semiconductor light emitting element.

6. The light emitting device of claim 1, wherein
a layer through which the first light and the second light pass is formed around the semiconductor light emitting element to be in contact with part of the semiconductor light emitting element except for the light emitting surface.

7. The light emitting device of claim 1, further comprising:
a lens which collects or scatters the first light and the second light.

8. The light emitting device of claim 1, wherein
the semiconductor light emitting element is made of a nitride semiconductor.

9. A surface light source, comprising:
multiple ones of the light emitting device of claim 1, arranged at regular intervals in a column direction and a line direction.

10. The light emitting device of claim 2, wherein
the wavelength conversion layer contains a fluorescent material.
